(19) United States
(12) Patent Application Publication
(10) Pub. No.: US 2026/0033028 A1
(43) Pub. Date: Jan. 29, 2026

(54) PHOTODETECTOR WITH P-TYPE COLLECTOR REGION ADJACENT TO FDTI STRUCTURE

(71) Applicant: Taiwan Semiconductor Manufacturing Company, Ltd., Hsinchu (TW)

(72) Inventors: Shih-Min Huang, Hsinchu County (TW); Tzu-Jui Wang, Fengshan City (TW); Chia-Chi Hsiao, Tianzhong Township (TW); Chi-Hsien Chung, New Taipei City (TW); Kuo-Chin Huang, Yilan City (TW); Chen-Jong Wang, Hsin-Chu (TW); Dun-Nian Yaung, Taipei City (TW)

(21) Appl. No.: 18/780,585

(22) Filed: Jul. 23, 2024

(51) Int. Cl. H01L 27/146

(52) U.S. Cl. CPC H10F 39/807; H10F 39/014; H10F 39/182; H10F 39/809; H10F 39/811

(57) ABSTRACT

Various embodiments of the present application are directed towards an image sensor. The image sensor includes a photodetector disposed in a semiconductor substrate. The photodetector comprises a collector region and a pinning region. The pinning region is disposed between the collector region and a front side of the semiconductor substrate. The pinning region and the semiconductor substrate comprise a first doping type and the collector region comprises a second doping type opposite the first doping type. An isolation structure is in the semiconductor substrate and adjacent to the photodetector. A doped liner region extends along opposing sidewalls of the isolation structure and comprises the first doping type. The doped liner region extends from sides of the collector and pinning regions to a sidewall of the isolation structure. The first doping type is n-type and the second doping type is p-type.

### BACKGROUND

Many modern-day electronic devices (e.g., smartphones, digital cameras, biomedical imaging devices, automotive imaging devices, etc.) comprise image sensors. The image sensors comprise one or more photodetectors (e.g., photodiodes, phototransistors, photoresistors, etc.) configured to absorb incident radiation and output electrical signals corresponding to the incident radiation. Some types of image sensors include charge-coupled device (CCD) image sensors and complementary metal-oxide-semiconductor (CMOS) image sensors. Compared to CCD image sensors, CMOS image sensors are favored due to low power consumption, small size, fast data processing, a direct output of data, and low manufacturing cost.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a diagram of some embodiments of an image sensor including a pixel having a photodetector with low leakage current.

FIG. 2A illustrates a cross-sectional view of some embodiments of an image sensor including a pixel having a photodetector with low leakage current, where the pixel spans a first IC chip and a second IC chip.

FIGS. 2B-2E illustrate cross-sectional views of some other embodiments of the image sensor of FIG. 2A.

FIG. 3 illustrates a top view of some embodiments of the image sensor of FIG. 2A taken along the line A-A′ of FIG. 2A.

FIGS. 4A and 4B illustrate cross-sectional views of some other embodiments of the image sensor of FIG. 2A.

FIG. 5 illustrates a top view of some embodiments of the image sensor of FIG. 4B taken along the line A-A′ of FIG. 4B.

FIG. 6 illustrates a circuit diagram of some other embodiments of the image sensor of FIG. 2A in which the image sensor further includes a third IC chip.

FIG. 7 illustrates a cross-sectional view of some other embodiments of the image sensor of FIG. 2A in which the image sensor further includes a third IC chip.

FIGS. 8-21 illustrate cross-sectional views of some embodiments of a method of forming an image sensor comprising photodetectors having low leakage current.

FIG. 22 illustrates a flow diagram of some embodiments of a method of forming an image sensor comprising photodetectors having low leakage current.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A complementary metal-oxide-semiconductor (CMOS) image sensor includes an array of photodetectors in a semiconductor substrate. Each photodetector comprises a p-n junction between a collector region and adjacent regions of the semiconductor substrate. The photodetector is configured to accumulate photogenerated charge, and a transfer transistor is configured to selectively transfer the photogenerated charge to a floating diffusion. The photodetectors may be separated from one another by a deep trench isolation (DTI) structure disposed in trenches of the semiconductor substrate. The DTI structure provides good electrical and optical isolation between the photodetectors. The collector region of the photodetector comprises an n-type dopant (e.g., arsenic, antimony, phosphorus, etc.) and the regions of the semiconductor substrate adjacent to the collector region comprise a p-type dopant (e.g., boron, indium, aluminum, etc.). Further, the floating diffusion node comprises the n-type dopant, and the transfer transistor and other pixel devices (e.g., reset transistor, select transistor, source-follower transistor, etc.) may each be configured as n-channel transistors (e.g., n-channel metal-oxide-semiconductor (NMOS) transistors) to facilitate readout of the photodetector.

While the DTI structure provides good electrical and optical isolation, issues may arise during fabrication or use of the CMOS image sensor. For example, during fabrication of the CMOS image sensor, the collector region is formed in the semiconductor substrate and the DTI structure is formed in the semiconductor substrate adjacent to the collector region. The DTI structure may be formed by etching a front-side surface of the semiconductor substrate to form trenches and subsequently forming (e.g., by a thermal oxidation process) a DTI material in the trenches. The DTI structure comprises the DTI material that may, for example, be or comprise an oxide, such as silicon dioxide. While forming the DTI structure, the n-type dopants (e.g., arsenic and/or phosphorus) of the collector region has a first segregation coefficient that is greater than a second segregation coefficient of the p-type dopant (e.g., boron) in the semiconductor substrate. As a result, the n-type dopant of the collector region may be prone to diffuse out from the collector region and accumulate along an interface between the DTI structure and the semiconductor substrate. For example, the n-type dopant may diffuse out of the collector region during a thermal oxidation process performed to form the DTI structure or one or more anneal processes performed during subsequent fabrication processes (e.g., utilized to form the transfer transistor, other pixel devices, and/or an interconnect structure on the semiconductor substrate). This may cause unwanted leakage current (e.g., dark current) and/or white pixels in the CMOS image sensor. Further, the out diffusion of the n-type dopant from the collector region to the DTI structure may reduce a size of the collector region, thereby reducing a full wall capacity of the photodetector and reducing an overall performance of the CMOS image sensor.

Accordingly, various embodiments of the present disclosure are directed towards an image sensor comprising a photodetector with low leakage current. In some embodiments, the image sensor includes a photodetector having a collector region and a pinning region in a semiconductor substrate. The collector region comprises p-type dopants, and the pinning region and other regions of the semiconductor substrate adjacent to the collector region comprise n-type dopants. A deep trench isolation (DTI) structure is arranged in the semiconductor substrate and is adjacent to the collector region. A doped liner region is disposed between the DTI structure and the photodetector and comprises n-type dopants. The n-type dopants (e.g., arsenic, phosphorus, etc.) of the doped liner region have a first segregation coefficient (e.g., about 3 to 10) greater than a second segregation coefficient (e.g., about 0.1 to 0.3) of the p-type dopants (e.g., boron) of the collector region. The first and second segregation coefficients are the segregation ratios at an interface between the semiconductor substrate and the DTI structure. The larger first segregation coefficient of the n-type dopants of the doped liner region (and other doped regions of the semiconductor substrate adjacent to the collector region) cause the n-type dopants to accumulate along the interface between the semiconductor substrate and the DTI structure. Further, the smaller second segregation coefficient of the p-type dopants of the collector region mitigate out diffusion of the p-type dopants from the collector region (e.g., towards the interface DTI structure). For example, during a thermal oxidation process utilized to form the DTI structure, the n-type dopants may accumulate along an interface between the DTI structure and the semiconductor substrate while the p-type dopants of the collector region are less likely to diffuse towards the DTI structure. As a result, dopant segregation between the collector region and adjacent regions of the semiconductor substrate may be increased. Accordingly, unwanted leakage current (e.g., dark current) and/or white pixels in the image sensor are reduced. Further, a size of the collector region may be maintained or increased, thereby increasing a full well capacity of the photodetector. Therefore, an overall performance of the image sensor is increased.

FIG. 1 illustrates a diagram 100 of some embodiments of an image sensor including a pixel having a photodetector with low leakage current.

The image sensor comprises a pixel 104. The pixel 104 comprises a photodetector 106 disposed in a first substrate 102a, a transfer transistor 116, and a plurality of pixel transistors 120, 122, 124. The first substrate 102 has a front side 102f opposite a back side 102b. The first substrate 102 comprises a first doping type (e.g., n-type). In some embodiments, the photodetector 106 comprises a collector region 108 and a pinning region 110 disposed between a top of the collector region 108 and the front side 102f of the first substrate 102. The collector region 108 comprises a second doping type (e.g., p-type) opposite the first doping type. The pinning region 110 comprises the first doping type (e.g., n-type). In various embodiments, the first doping type is n-type and the second doping type is p-type. The photodetector 106 is configured to convert incident light into an electrical signal. In various embodiments, the photodetector 106 is configured as a photodiode, a pinned photodiode, or some other suitable photodetector. In some embodiments, the collector region 108 is referred to as a first doped region and the pinning region 110 is referred to as a second doped region.

An isolation structure 114 is disposed in the first substrate 102. In some embodiments, the isolation structure 114 continuously extends from the front side 102f of the first substrate 102 to the back side 102b. In various embodiments, the isolation structure 114 extends around an outer perimeter for the photodetector 106 and is configured to provide optical and electrical isolation for the photodetector 106. The isolation structure 114 may be referred to as a deep trench isolation (DTI) structure or a front side deep trench isolation (FDTI) structure. A doped liner region 112 is disposed in the first substrate 102 and extends along opposing sidewalls of the isolation structure 114. The doped liner region 112 comprises the first doping type (e.g., n-type) and extends from one or more sides of the photodetector 106 to the isolation structure 114.

The transfer transistor 116 is disposed on the first substrate 102 and comprises a transfer gate dielectric 132, a transfer gate electrode 130 on the transfer gate dielectric 132, and a sidewall spacer 134 along sidewalls of the transfer gate electrode 130 and the transfer gate dielectric 132. In some embodiments, the transfer transistor 116 is configured to selectively transfer accumulated charge at the photodetector 106 to a floating diffusion node 118. The floating diffusion node 118 is disposed in the first substrate 102 and comprises the second doping type (e.g., p-type). In various embodiments, the transfer gate electrode 130 is spaced between the floating diffusion node 118 and the photodetector 106.

In some embodiments, the collector region 108 and the floating diffusion node 118 respectively comprise p-type dopants that may, for example, be or comprise boron, indium, aluminum, gallium, or some other suitable p-type dopant. In various embodiments, the first substrate 102 (e.g., regions of the first substrate 102 adjacent to the collector region 108 and/or the floating diffusion node 118), the pinning region 110, and the doped liner region 112 comprise n-type dopants, that may, for example, be or comprise arsenic, antimony, phosphorus, or some other suitable n-type dopant.

The plurality of pixel transistors 120, 122, 124 comprises a reset transistor 120, a source-follower transistor 122, and a select transistor 124. The reset transistor 120 has a first source/drain region coupled to the floating diffusion node 118 and a second source/drain region coupled to a reference voltage node 126. In some embodiments, the reference voltage node 126 is coupled to ground (e.g., 0 volts). In some embodiments, the first substrate 102 is electrically coupled to a power supply voltage node 128 that may, for example, be within a range of about 0.9 to 5 volts. The reset transistor 120 is gated by a reset signal RST and is configured to selectively electrically couple the floating diffusion node 118 to the reference voltage node 126. In various embodiments, the reset transistor 120 is configured to selectively couple the photodetector 106 to the reference voltage node 126 through coordination with the transfer transistor 116, thereby clearing accumulated charge at the photodetector 106. The source-follower transistor 122 has a first source/drain region coupled to a first source/drain region of the select transistor 124 and a second source/drain region coupled to the reference voltage node 126. The source-follower transistor 122 is gated by a charge at the floating diffusion node 118. In various embodiments, the source-follower transistor 122 is configured to buffer and/or amplify a voltage at the floating diffusion node 118 for non-destructive reading of the pixel 104. A second source/drain region of the select transistor 124 is coupled to an output terminal (not labeled). The select transistor 124 is configured to selectively pass the buffered and/or amplified voltage from the source-follower transistor 122 to the output terminal. In various embodiments, the transfer transistor 116 and the plurality of pixel transistors 120, 122, 124 are each configured as a p-type transistor (e.g., a p-channel metal-oxide-semiconductor (PMOS) transistor). In some embodiments, the transfer transistor 116 and the plurality of pixel transistors 120, 122, 124 may, for example, each be a metal-oxide-semiconductor field-effector transistor (MOSFET), fin field-effect transistor (FinFET), gate-all-around field-effect transistors (GAA FET), nanosheet FET, some other type of transistor, or any combination of the foregoing.

During operation of the image sensor incident radiation (e.g., incident light) impinges on the photodetector 106 to generate electron-hole pairs. In some embodiments, the formation of the electron-hole pair may release a mobile hole that is collected in the collector region 108, such that the photodetector 106 converts the incident radiation into an electrical signal. During fabrication of the image sensor, an etching process is performed to form trenches in the first substrate 102 and the trenches are subsequently filled with the isolation structure 114. The isolation structure 114 may, for example, be or comprise an oxide such as silicon dioxide, or some other suitable material. In various embodiments, the isolation structure 114 consists essentially of silicon dioxide. In various embodiments, the isolation structure 114 may be formed in the trenches by a thermal oxidation process.

The n-type dopants of the first substrate 102, the doped liner region 112, and the pinning region 110 have a first segregation coefficient k1 (e.g., within a range of about 3 to 10) that is greater than a second segregation coefficient k2 (e.g., within a range of about 0.1 to 0.3) of the p-type dopants of the collector region 108 and the floating diffusion node 118. In various embodiments, the first and second segregation coefficients k1, k2 respectively refer to a segregation ratio or distribution coefficient at an interface between the first substrate 102 and the isolation structure 114 that are defined by a ratio between a concentration of dopants in the isolation structure 114 and a concentration of dopants in the first substrate 102 when the isolation structure 114 is formed in a silicon substrate comprising the corresponding dopants. For example, k1=Cn₁₀₂/Cn₁₁₄, where C₁₀₂ is the concentration of n-dopants in the first substrate 102 at the interface and Cn₁₁₄ is the concentration of n-dopants in the isolation structure 114 at the interface. As a result of the doped liner region 112 comprising the n-type dopants with the higher first segregation coefficient k1 and being disposed along the interface between the isolation structure 114 and the first substrate 102, the n-type dopants may accumulate along the interface between the isolation structure 114 and the first substrate 102. This mitigates or prevents the p-type dopants of the collector region 108 from out diffusing to the interface between the isolation structure 114 and the first substrate 102, thereby increasing dopant segregation in the image sensor. As a result, dark current and/or white pixels are reduced, thereby decreasing leakage current and increasing an overall performance of the image sensor. Further, the p-type dopants in the collector region 108 being less likely to diffuse out during fabrication of the image sensor mitigates a decrease in size of the photodetector 106, thereby increasing and/or maintaining a full well capacity of the photodetector 106 and increasing the performance of the image sensor. Further, the transfer transistor 116 and the plurality of pixel transistors 120, 122, 124 each being configured as a p-type transistor facilitates accurate and efficient readout of the photodetector 106.

In various embodiments, a doping concentration of a bulk region of the first substrate 102 is within a range of about 10¹⁴ to 10¹⁶ atoms/cm³ or some other suitable value. In some instances, the bulk region of the first substrate 102 are regions of the first substrate 102 adjacent to doped regions of the photodetector 106, the floating diffusion node 118, the doped liner region 112, and the pinning region 110. A doping concentration of the collector region 108 is, for example, within a range of about 5*10¹⁶ to 10¹⁸ atoms/cm³ or some other suitable value. The doping concentration of the collector region 108 is greater than the doping concentration of the bulk region of the first substrate 102. A doping concentration of the pinning region 110 is, for example, within a range of about 10¹⁷ to 10¹⁹ atoms/cm³ or some other suitable value. In some embodiments, the doping concentration of the pinning region 110 is greater than the doping concentration of the collector region 108. This, in part, facilitates the pinning region 110 pinning a depletion region between the pinning region 110 and the collector region 108, thereby increasing a quantum efficiency (QE) of the photodetector 106 and further decreasing dark current.

A doping concentration of the doped liner region 112 is, for example, within a range of about 10¹⁷ to 10¹⁹ atoms/cm³ or some other suitable value. In various embodiments, the doping concentration of the doped liner region 112 is equal to the doping concentration of the pinning region 110, thereby further increasing the QE of the photodetector 106. Further, the doping concentration of the doped liner region 112 is greater than the doping concentration of the collector region 108. As a result, negative effects (e.g., dark current, white pixels, etc.) from defects (e.g., dangling bonds) along the isolation structure 114 may be reduced, thereby decreasing leakage current in the image sensor. A doping concentration of the floating diffusion node 118 is, for example, within a range of about 5*10¹⁶ to 10¹⁸ atoms/cm³ or some other suitable value. In further embodiments, the doping concentration of the floating diffusion node 118 is equal to the doping concentration of the collector region 108.

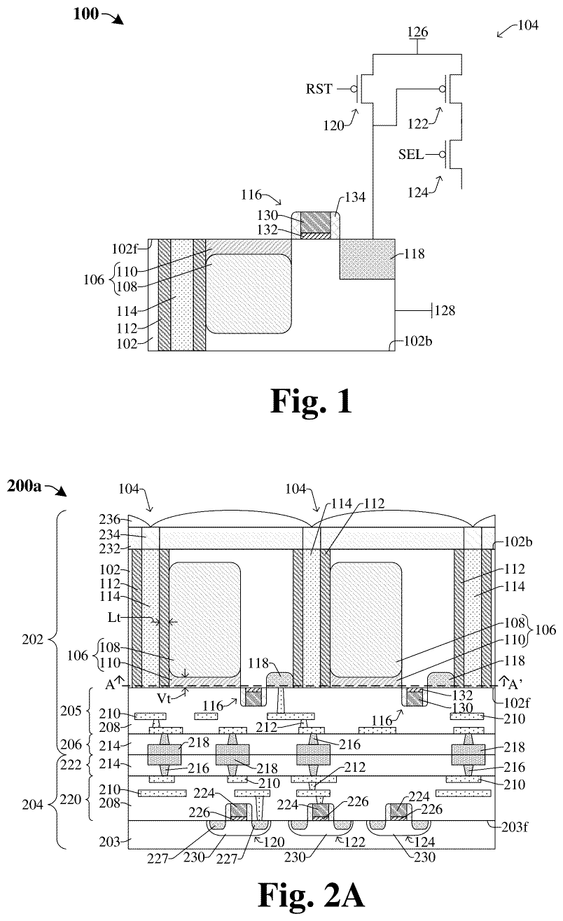

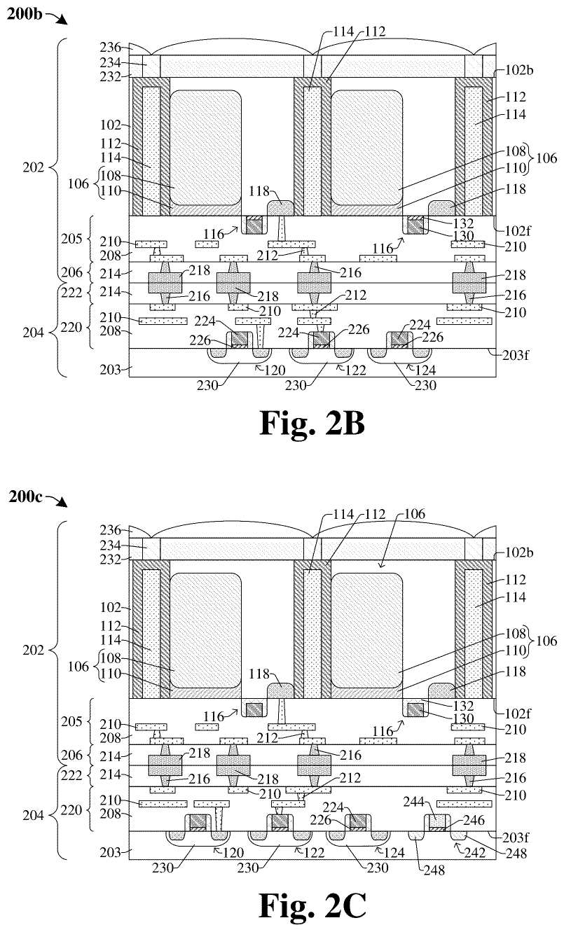

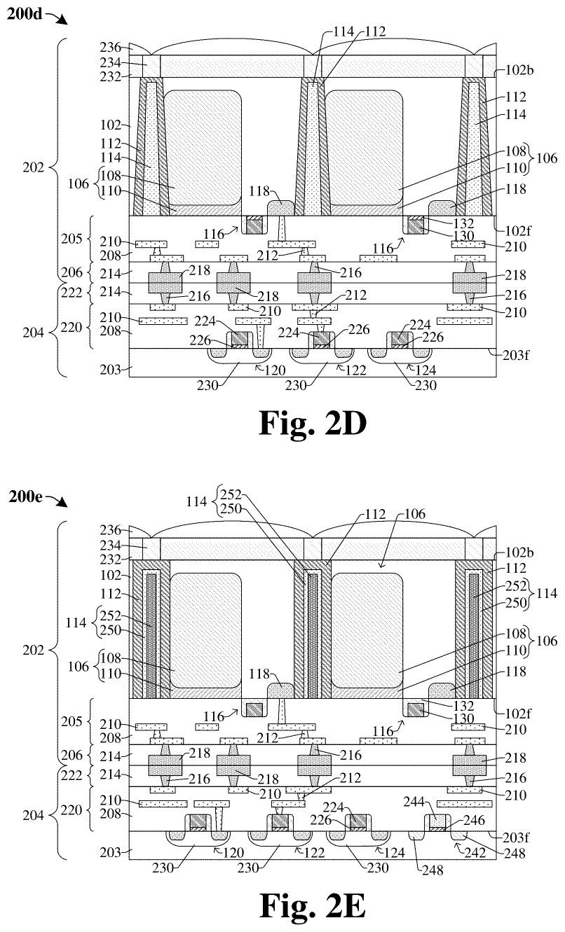

FIG. 2A illustrates a cross-sectional view 200a of some embodiments of an image sensor comprising a first IC chip and a second IC chip.

In some embodiments, the image sensor comprises a first IC chip 202 vertically stacked with a second IC chip 204. The first IC chip 202 comprises a first substrate 102, a first interconnect structure 205 on a front side 102f of the first substrate 102, and a first bond structure 206 on the first interconnect structure 205. The first substrate 102 may, for example, be or comprise silicon, epitaxial silicon, silicon-germanium (SiGe), a silicon-on-insulator (SOI) substrate, or some other suitable substrate material. The first substrate 102 comprises first dopants having a first doping type. In some embodiments, the first doping type is n-type and the first dopants may, for example, be or comprise one or more of arsenic, phosphorus, antimony, or some other suitable n-type dopant. A plurality of photodetectors 106 are disposed within the first substrate 102. The photodetectors respectively comprises a pinning region 110 and a collector region 108. The pinning region 110 comprises the first doping type and the collector region 108 comprises second dopants having a second doping type opposite the first doping type. In various embodiments, the second doping type is p-type and the second dopants may, for example, be or comprise one or more of boron, indium, aluminum, gallium, or some other suitable p-type dopant. In some embodiments, the pinning region 110 continuously extends from a bottom of the collector region 108 to the front side 102f of the first substrate 102. A floating diffusion node 118 is disposed in the first substrate 102 adjacent to a corresponding photodetector 106. The floating diffusion node 118 comprises the second doping type (e.g., p-type).

A plurality of transfer transistors 116 are disposed on the front side 102f of the first substrate 102 and are each adjacent to a corresponding photodetector 106. The transfer transistors 116 each comprise a transfer gate dielectric 132 on the first substrate 102 and a transfer gate electrode 130 on the transfer gate dielectric 132. An isolation structure 114 is disposed in the first substrate 102 between adjacent photodetectors 106. In various embodiments, the isolation structure 114 continuously wraps around an outer perimeter of each of the photodetectors 106. In some embodiments, the isolation structure 114 continuously vertically extends from the front side 102f of the first substrate 102 to a back side 102b of the first substrate 102. The isolation structure 114 may, for example, be or comprise silicon dioxide, silicon oxynitride, silicon oxycarbide, another dielectric material, or any combination of the foregoing. The isolation structure 114 is configured to increase electrical and optical isolation between the photodetectors 106. A doped liner region 112 is disposed on the first substrate 102 and extends along sidewalls of the isolation structure 114. The doped liner region 112 comprises the first doping type (e.g., n-type).

In some embodiments, the doped liner region 112 continuously extends along sidewalls of the isolation structure 114 from the front side 102f of the first substrate to the back side 102b of the first substrate 102. In various embodiments, a lateral thickness Lt of the doped liner region 112 along the isolation structure 114 is less than a vertical thickness Vt of the pinning region 110. This, in part, facilitates the doped liner region 112 mitigating out diffusion of p-type dopants from the collector region 108 during formation of the isolation structure 114 while maintaining or increasing a size of the collector region 108, thereby increasing the QE of the photodetector 106. The doped liner region 112 continuously extends from a side of the collector region 108 to a side of the pinning region 110. Further, the doped liner region 112 is disposed between the floating diffusion node 118 and the isolation structure 114. As a result, out diffusion of p-type dopants in the floating diffusion node 118 is decreased, thereby further decreasing leakage current and increasing a readout efficiency of the pixels 104.

In yet further embodiments, the pinning region 110 comprises a first n-type dopant (e.g., antimony) and the doped liner region 112 comprises a second n-type dopant (e.g., arsenic) different from the first n-type dopant. In various embodiments, a size (e.g., atomic radius) of the first n-type dopant is greater than a size (e.g., atomic radius) of the second n-type dopant. By virtue of the size of the first n-type dopant being greater than that of the second n-type dopant, the first n-type dopant is less likely to move through the lattice of the first substrate 102 and the second n-type dopant is more likely to move through the lattice of the first substrate 102. As a result, the second n-type dopant in the doped liner region 112 may more easily accumulate along and interface between the first substrate 102 along the isolation structure 114, thereby enhancing dopant segregation and mitigating dark current and/or white pixels. Further, the first n-type dopants being less likely to diffuse out facilitates the pinning region 110 increasing the QE of the photodetector 106 while maintaining or increasing the size of the collector region 108, thereby increasing the full well capacity of the photodetector 106. In various embodiments, the first n-type dopant of the pinning region 110 is or comprises antimony and the second n-type dopant of the doped liner region 112 is or comprises arsenic.

A grid structure 234 is arranged on the back side 102b of the first substrate 102. The grid structure 234 comprises sidewalls defining openings over the photodetectors 106. The grid structure 234 is configured to mitigate cross talk between adjacent photodetectors 106. In various embodiments, the grid structure 234 directly overlies and/or is aligned with the isolation structure 114. A plurality of light filters 232 are arranged on the back side 102b of the first substrate 102. The light filters 232 are each configured to pass a first range of wavelengths while blocking a second range of wavelengths different from the first range of wavelengths. A plurality of micro-lenses 236 are disposed on the plurality of light filters 232 and are configured to focus incident light towards the photodetectors 106.

The second IC chip 204 comprises a second substrate 203, a second interconnect structure 220 on a front side 203f of the second substrate 203, and a second bond structure 222 on the second interconnect structure 220. The second substrate 203 may, for example, be or comprise silicon, epitaxial silicon, SiGe, an SOI substrate, or some other suitable substrate material. The second substrate 203 comprises the second doping type (e.g., p-type). A plurality of pixel transistors 120, 122, 124 are disposed in on the second substrate 203. The first and second interconnect structures 205, 220 respectively comprise an interconnect dielectric structure 208, a plurality of conductive wires 210, and a plurality of conductive vias 212. The first and second interconnect structures 205, 220 are configured to facilitate electrical coupling between and/or on the first IC chip 202 and the second IC chip 204. The first bond structure 206 meets the second bond structure 222 at a first bond interface that comprises conductor-to-conductor bonds and dielectric-to-dielectric bonds. The first and second bond structures 206, 222 respectively comprise a bond dielectric structure 214, a plurality of conductive bond contacts 216, and a plurality of conductive bond pads 218.

The plurality of pixel transistors 120, 122, 124 are arranged on the front side 203f of the second substrate 203. The plurality of pixel transistors 120, 122, 124 respectively comprise a gate dielectric structure 226 on the second substrate 203, a gate electrode 224 on the gate dielectric structure 226, and a pair of source/drain regions 227 in a corresponding well region 230. In some embodiments, the well region 230 comprises the first doping type (e.g., n-type) and the pair of source/drain regions 227 each comprise the second doping type (e.g., p-type). In further embodiments, the gate electrode 224 of each of the pixel transistors 120, 122, 124 comprises one or more gate electrode layers having a p-type work function. In various embodiments, the transfer gate electrode 130 and the gate electrodes 224 may comprise one or more gate electrode layers that respectively comprise p-type polysilicon, a metal with a p-type work function, or some other suitable function. In some embodiments, a p-type work function may, for example, be a work function within about 4.5 to 5.1 eV, greater than about 4.8 eV, 5.0 eV, or 5.2 eV, or some other suitable value. In some embodiments, a metal with a p-type work function may, for example, be or comprise titanium aluminum nitride, tungsten carbon nitride, nickel, platinum, some other suitable p-type work function metal, or any combination of the foregoing. The transfer gate electrode 130 and the gate dielectric structure 226 may, for example, respectively be or comprise silicon dioxide, hafnium oxide, zirconium oxide, some other suitable dielectric material, or any combination of the foregoing.

In various embodiments, the image sensor comprises a plurality of pixels 104 that each span the first IC chip 202 and the second IC chip 204. In some embodiments, the pixels 104 respectively comprise one or more of the photodetectors 106, one or more of the transfer transistors 116, and the plurality of pixel transistors 120, 122, 124. For example, each of the pixels 104 may comprise four transistors (e.g., a single transfer transistor, a reset transistor, a select transistor, and a source-follower transistor) and an individual photodetector. The pixels 104 span the first and second IC chips 202, 204 by the corresponding transfer transistor 116 and photodetector 106 being disposed in the first IC chip 202 and the corresponding plurality of pixel transistors 120, 122, 124 being disposed in the second IC chip 204. Disposing the plurality of pixel transistors 120, 122, 124 in the second IC chip 204 creates more space on the first substrate 102 of the first IC chip 202 for the photodetectors 106. As a result, a density of the photodetectors 106 in the first IC chip 202 may be increased and feature sizes of the pixels 104 in the first IC chip 202 may be scaled down while maintaining good electrical and optical isolation between adjacent pixels in the plurality of pixels 104.

FIG. 2B illustrates a cross-sectional view 200b of some other embodiments of the image senor of FIG. 2A, where the isolation structure 114 extends from the front side 102f of the first substrate 102 to a point below the back side 102b of the first substrate 102.

In some embodiments, a top surface of the isolation structure 114 is vertically offset from the back side 102b of the first substrate 102. The doped liner region 112 continuously extends from sidewalls of the isolation structure 114 to the top surface of the isolation structure 114. In various embodiments, the doped liner region 112 continuously extends from the top surface of the isolation structure 114 to the back side 102b of the first substrate 102.

FIG. 2C illustrates a cross-sectional view 200c of some other embodiments of the image sensor of FIG. 2A, where an in-pixel transistor 242 is disposed on the second substrate 203.

The in-pixel transistor 242 is part of an in-pixel circuit. In some embodiments, the in-pixel circuit includes a column amplifier, a correlated double sampling (CDS) circuit, some other suitable circuit, or any combination of the foregoing. The in-pixel transistor 242 comprises a gate dielectric structure 246 on the second substrate 203, a gate electrode 244 on the gate dielectric structure 246, and a pair of source/drain regions 248 in the second substrate 203 on opposing sides of the gate electrode 244. In various embodiments, the pair of source/drain regions 248 comprise the first doping type (e.g., n-type). In some embodiments, the in-pixel transistor 242 is configured as an n-type transistor and the gate electrode 244 comprises one or more gate electrode layers having an n-type work function. The in-pixel transistor 242 may, for example, be a MOSFET, FinFET, GAA FET, nanosheet FET, or some other type of transistor.

FIG. 2D illustrates a cross-sectional view 200d of some other embodiments of the image sensor of FIG. 2A, where sidewalls of the isolation structure 114 are slanted relative to the front side 102f of the first substrate 102. In various embodiments, the isolation structure 114 comprises a plurality of isolation segments disposed between each photodetector 106 and a width of each isolation segment continuously decreases from the front side 102f to the back side 102b.

FIG. 2E illustrates a cross-sectional view 200e of some other embodiments of the image sensor of FIG. 2A, where the isolation structure 114 comprises a first isolation layer 250 and a second isolation layer 252. In some embodiments, a material of the first isolation layer 250 is different from a material of the second isolation layer 252. In some embodiments, the first isolation layer 250 may, for example, be or comprise silicon dioxide or some other suitable material. The second isolation layer 252 may, for example, be or comprise silicon dioxide, silicon oxynitride, silicon oxycarbide, a metal such as aluminum, tungsten, titanium nitride, or some other suitable material. In yet further embodiments, the first isolation layer 250 may, for example, be or comprise epitaxial silicon, doped epitaxial silicon, doped silicon oxide, or the like. In various embodiments, the first isolation layer 250 may comprise doped epitaxial silicon or doped silicon oxide having the first doping type (e.g., n-type) with a doping concentration that may be equal to or less than that of the doped liner region 112. In such embodiments, the first isolation layer 250 comprising the first doping type further enhances dopant segregation and/or mitigates issues (e.g., dark current) due to defects (e.g., dangling bonds) in the first substrate 102 along the isolation structure 114.

FIG. 3 illustrates a top view 300 of some embodiments of the image sensor of FIG. 2A taken along the line A-A′ of FIG. 2A.

As illustrated in FIG. 3, when viewed from above the isolation structure 114 has a grid layout. The isolation structure 114 continuously wraps around the photodetector (106 of FIG. 2A) of each pixel 104. In various embodiments, the pinning region 110 directly overlies the collector region (108 of FIG. 2A) of each of the photodetectors (106 of FIG. 2A). In some embodiments, an outer perimeter of the pinning region 110 is aligned with an outer perimeter of the collector region (108 of FIG. 2A). A power supply voltage node 304 is disposed in the first substrate 102 in a region of each of the pixels 104, where the region of each of the pixels 104 is defined by inner sidewalls of the isolation structure 114. The power supply voltage node 304 represents a connection to the first substrate 102 where a supply voltage is applied to a bulk region of the first substrate 102. In some embodiments, the power supply voltage node 304 is or comprises a doped region of the first substrate 102 comprising the first doping type (e.g., n-type) with a doping concentration greater than that of the collector region (108 of FIG. 2A).

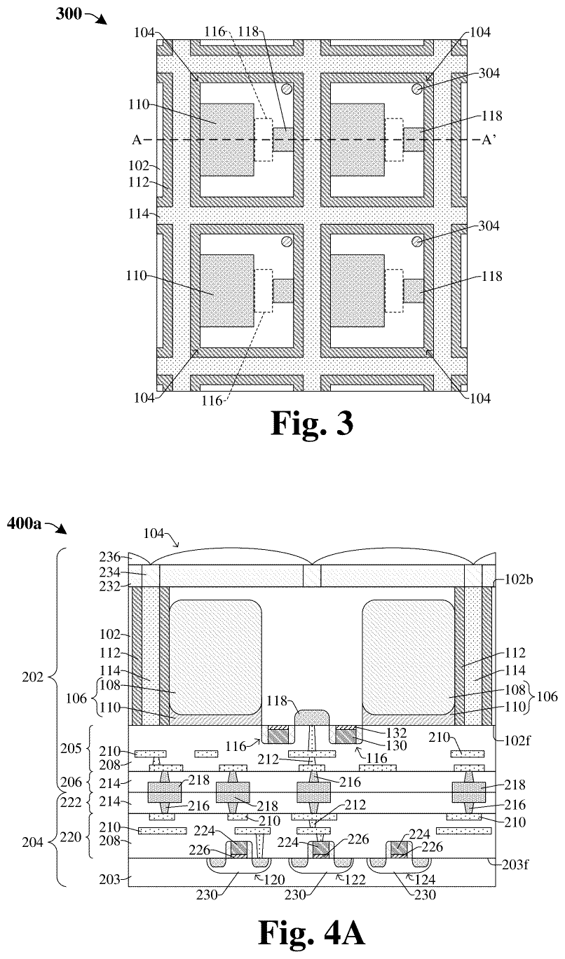

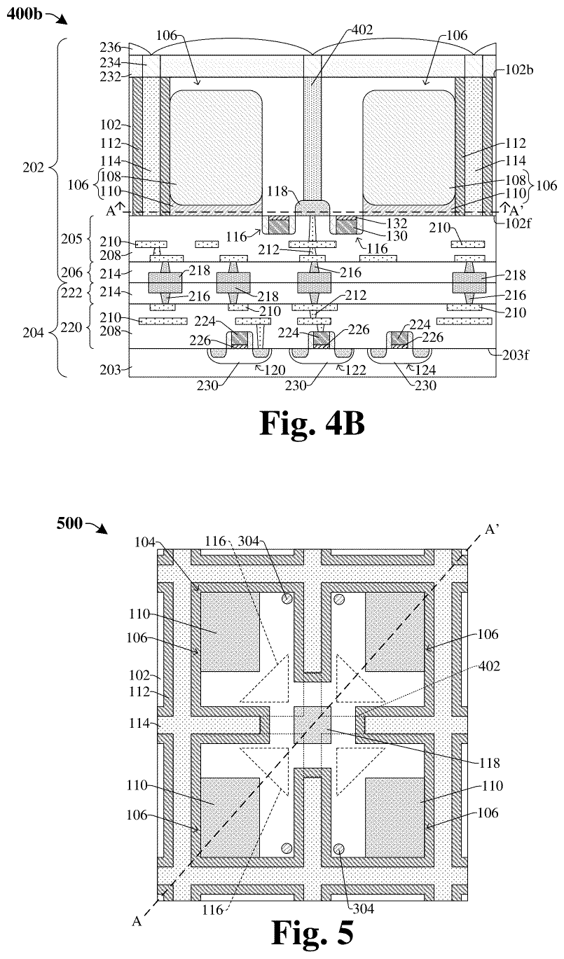

FIG. 4A illustrates a cross-sectional view 400a of some other embodiments of the image sensor of FIG. 2A. In some embodiments, the image sensor comprises a pixel 104 having a shared pixel layout, where the floating diffusion node 118 is arranged between two or more photodetectors 106. The pixel 104 may, for example, have a 1×2 shared layout, a 2×2 shared layout, or the like.

FIG. 4B illustrates a cross-sectional view 400b of some other embodiments of the image sensor of FIG. 4A, where a second isolation structure 402 is disposed in the first substrate 102 and is arranged over the floating diffusion node 118. In some embodiments, the second isolation structure 402 continuously extends from the back side 102b of the first substrate 102 to a top of the floating diffusion node 118. The second isolation structure 402 may, for example, be or comprise silicon dioxide, silicon carbide, silicon nitride, another dielectric material, or any combination of the foregoing. In yet further embodiments, a second doped liner region (not shown) comprising n-type dopants may be disposed along sidewalls of the second isolation structure 402.

FIG. 5 illustrates a top view 500 of some embodiments of the image sensor of FIG. 4B taken along the line A-A′ of FIG. 4B.

As illustrated in FIG. 5, in some embodiments the pixel 104 comprises four photodetectors 106 and a transfer transistor 116 arranged between the floating diffusion node 118 and a corresponding photodetector 106. In some embodiments, the second isolation structure 402 directly contacts sidewalls of the isolation structure 114 and directly overlies the floating diffusion node 118. In various embodiments, the second isolation structure 402 has a cross-shape. In further embodiments, the doped liner region 112 continuously extends from the front side 102f of the first substrate 102 to a bottom surface of the second isolation structure 402.

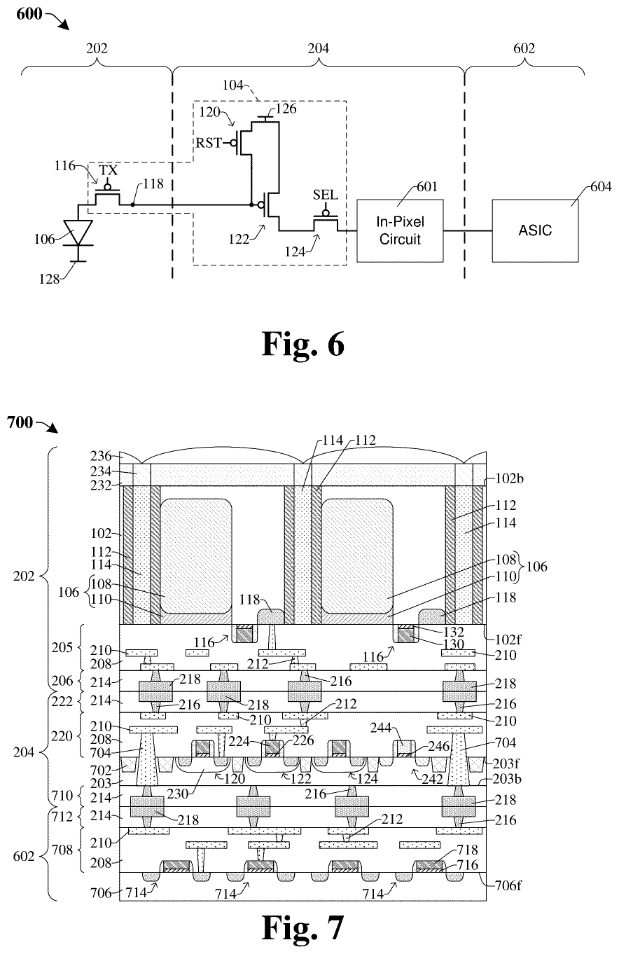

FIG. 6 illustrates a circuit diagram 600 of some other embodiments of the image sensor of FIG. 2A in which the image sensor further includes a third IC chip.

The image sensor comprises a first IC chip 202, a second IC chip 204, and a third IC chip 602. In some embodiments, the first IC chip 202 and the second IC chip 204 are each configured as illustrated and/or described in FIGS. 2A, 2B, 2C, 2D, 2E, 4A, or 4B. The image sensor comprises a pixel 104 that spans the first IC chip 202 and the second IC chip 204. The pixel 104 comprises a photodetector 106, a transfer transistor 116, and a plurality of pixel transistors 120, 122, 124. The photodetector 106 and transfer transistor 116 are arranged on the first IC chip 202. In some embodiments, the photodetector 106 and the transfer transistor 116 are coupled in series between the floating diffusion node 118 and a power supply voltage node 128. The transfer transistor 116 is gated by a transfer signal TX. In some embodiments, an anode of the photodetector 106 is electrically coupled to the transfer transistor 116 and a cathode of the photodetector 106 is electrically coupled to a power supply voltage node 128.

The plurality of pixel transistors 120, 122, 124 are arranged on the second IC chip 204. The plurality of pixel transistors 120, 122, 124 comprise a reset transistor 120, a source-follower transistor 122, and a select transistor 124. The reset transistor 120 is coupled in series between a reference voltage node 126 and the floating diffusion node 118. The reset transistor 120 is gated by a reset signal RST. The source-follower transistor 122 is coupled in series between the reference voltage node 126 and the select transistor 124. A gate of the source-follower transistor 122 is directly electrically coupled to the floating diffusion node 118. The select transistor 124 is gated by a select signal SEL and is coupled in series between the source-follower transistor 122 and an in-pixel circuit 601. In various embodiments, by appropriately biasing the transfer transistor 116 and the plurality of pixel transistors 122, 122, 124, an electrical signal corresponding to incident light detected by the photodetector 106 is provided at an output of the pixel 104 (e.g., an output of the select transistor 124) and to the in-pixel circuit 601. The in-pixel circuit 601 is disposed on the second IC chip 204. In some embodiments, the in-pixel circuit 601 includes a column amplifier, a correlated double sampling (CDS) circuit, or some other suitable circuit. The in-pixel circuit 601 may be configured to perform addition processing (e.g., amplification, noise cancelation, etc.) on the electrical signal output at the pixel 104 before passing the electrical signal to an application-specific integrated circuit (ASIC) 604 arranged on the third IC chip 602. By virtue of the plurality of pixel transistors 120, 122, 124 and the in-pixel circuit 601 being disposed on the second IC chip 204, fewer devices (e.g., transistors) of the pixel 104 are disposed on the first IC chip 202. This facilitates scaling down sizes of devices (e.g., photodetectors) on the first IC chip 202 and/or increases a number of photodetectors on the first IC chip 202, thereby increasing performance of the image sensor.

FIG. 7 illustrates a cross-sectional view 700 of some other embodiments of the image sensor of FIG. 2A in which the image sensor further includes a third IC chip.

The image sensor comprises the first IC chip 202, the second IC chip 204, and a third IC chip 602 vertically stacked with one another. In various embodiments, the first IC chip 202 and the second IC chip 204 may be configured as illustrated and/or described in FIGS. 2A, 2B, 2C, 2D, 2E, 4A, or 4B. In some embodiments, the third IC chip 602 comprises an ASIC (e.g., 604 of FIG. 6) electrically coupled to the second IC chip 204. The ASIC on the third IC chip 602 may, for example, comprise one or more of an analog-to-digital conversion (ADC) circuit, an image processing circuit, a buffering circuit, or the like.

In various embodiments, the second IC chip 204 further includes a shallow trench isolation (STI) structure 702 disposed in the second substrate 203, a plurality of through substrate vias (TSVs) 704 extending from the second substrate 203 to the second interconnect structure 220, and a third bond structure 710 disposed on a back side 203b of the second substrate 203. The STI structure 702 is spaced between the pixel transistors 120, 122, 124 and the one or more in-pixel transistors 242, and is configured to provide electrical isolation between adjacent devices. The TSVs 704 are configured to electrically couple the third bond structure 710 to the second interconnect structure 220.

The third IC chip 602 comprises a third substrate 706, a third interconnect structure 708 on a front side 706f of the third substrate 706, a fourth bond structure 712 on the third interconnect structure 708, and a plurality of semiconductor devices 714 in and/or on the third substrate 706. In some embodiments, the third interconnect structure 708 comprises a plurality of conductive wires 210 and a plurality of conductive vias 212 disposed in an interconnect dielectric structure 208. The third interconnect structure 708 is configured to provide electrical coupling to and/or between the plurality of semiconductor devices 714. The third and fourth bond structures 710, 712 respectively comprise a plurality of conductive bond contacts 216 and a plurality of conductive bond pads 218 disposed in a bond dielectric structure 214. The third bond structure 710 of the second IC chip 204 is bonded to the fourth bond structure 712 of the third IC chip 602, such that a second bond interface is disposed between the second IC chip 204 and the third IC chip 602.

The third substrate 706 may, for example, be or comprise silicon, epitaxial silicon, SiGe, a SOI substrate, or some other suitable substrate material. The plurality of semiconductor devices 714 are disposed on the third substrate 706 and form the ASIC. In various embodiments, the semiconductor devices 714 are transistors and may comprise at least one n-type transistor and at least one p-type transistor. The semiconductor devices 714 may, for example, be MOSFETs, FinFETS, GAA FETs, nanosheet field-effect transistors, some other suitable transistor, or any combination of the foregoing.

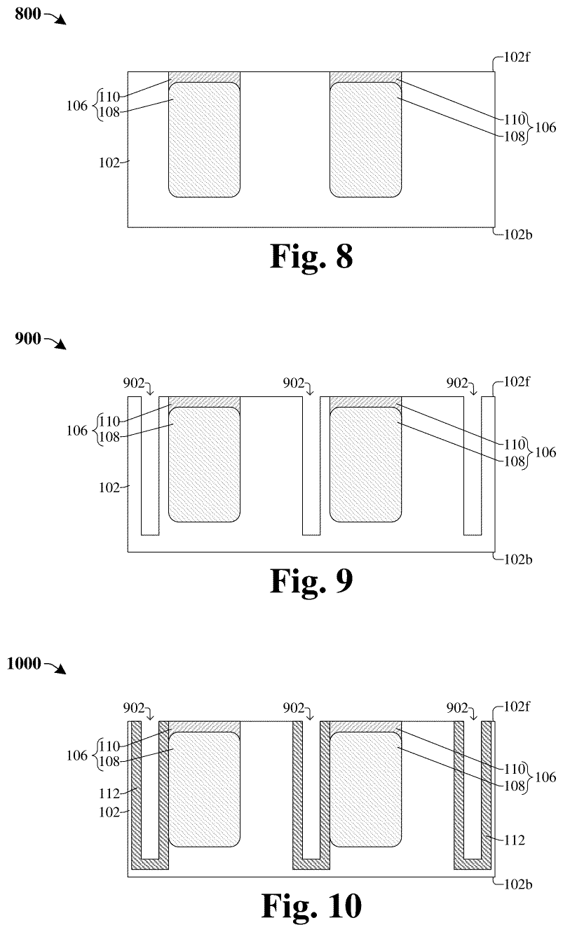

FIGS. 8-21 illustrate various cross-sectional views 800-2100 of some embodiments of a method of forming an image sensor comprising photodetectors having low leakage current. Although the cross-sectional views 800-2100 shown in FIGS. 8-21 are described with reference to a method, it will be appreciated that the structures shown in FIGS. 8-21 are not limited to the method but rather may stand alone separate of the method. Although FIGS. 8-21 are described as a series of acts, it will be appreciated that these acts are not limiting in that the order of the acts can be altered in other embodiments, and the methods disclose are also applicable to other structures. In other embodiments, some acts that are illustrated and/or described may be omitted in whole or in part.

As shown in cross-sectional view 800 of FIG. 8, a first substrate 102 is provided and a plurality of photodetectors 106 are formed in the first substrate 102. The first substrate 102 comprises first dopants having a first doping type (e.g., n-type). In some embodiments, the first doping type is n-type and the first dopants may be or comprise arsenic, antimony, phosphorus, some other suitable N-type dopant, or any combination of the foregoing. In various embodiments, a doping concentration of the first substrate 102 is within a range of about 10¹⁴ to 10¹⁶ atoms/cm³ or some other suitable value. The first substrate 102 may, for example, be or comprise silicon, epitaxial silicon, silicon-germanium (SiGe), a silicon-on-insulator (SOI) substrate, or some other suitable substrate material. The first substrate 102 has a front side 102f opposite a back side 102b.

The photodetectors 106 respectively comprise a collector region 108 and a pinning region 110. The collector region 108 and the pinning region 110 are doped regions of the first substrate 102 and may be formed by an ion implantation process. The collector region 108 is formed by a first ion implantation process that includes implanting second dopants having a second doping type (e.g., p-type) into the first substrate 102. In some embodiments, the second doping type is p-type and the second dopants may be or comprise boron, indium, aluminum, gallium, some other suitable p-type dopant, or any combination of the foregoing. The pinning region 110 is formed by a second ion implantation process that includes implanting the first dopants (e.g., arsenic, antimony, phosphorus, etc.) into the first substrate 102 with a higher doping concentration than that of adjacent regions of the first substrate 102. The pinning region 110 and a bulk region of the first substrate 102 surround the collector region 108, such that boundaries of the collector region 108 are demarcated by PN junctions. In various embodiments, after the first ion implantation process and/or the second ion implantation process, an anneal process is performed.

In some embodiments, a doping concentration of the collector region 108 is within a range of about 10¹⁶ to 10¹⁸ atoms/cm³ or some other suitable value. In various embodiments, a doping concentration of the pinning region 110 is within a range of about 10¹⁷ to 10¹⁹ atoms/cm³ or some other suitable value. In further embodiments, the doping concentration of the collector region 108 is greater than the doping concentration of the first substrate 102 and the doping concentration of the pinning region 110 is greater than the doping concentration of the collector region 108.

As shown in cross-sectional view 900 of FIG. 9, a patterning process is performing on the first substrate 102 to form a plurality of trenches 902 in the first substrate 102. In some embodiments, the patterning process includes: forming a masking layer (not shown) on the front side 102f of the first substrate 102; performing an etching process (e.g., a reactive ion etch, a plasma etch, etc.) on the first substrate 102 according to the masking layer; and performing a removal process to remove the masking layer. The trenches 902 extend from the front side 102f to a point above the back side 102b and are disposed between adjacent photodetectors 106. After the patterning process, sidewalls of the first substrate 102 defining the trenches 902 may comprise defects (e.g., dangling bonds) as a result of the etching process.

As shown in cross-sectional view 1000 of FIG. 10, a doped liner region 112 is formed in the first substrate 102 along the plurality of trenches 902. In some embodiments, the doped liner region 112 is formed by an ion implantation process that includes implanting the first dopants (e.g., arsenic, antimony, phosphorus, etc.) into the first substrate 102 with a higher doping concentration than that of adjacent regions of the first substrate 102. In various embodiments, the doped liner region 112 comprises the first doping type (e.g., n-type) with a doping concentration within a range of about 10¹⁷ to 10¹⁹ atoms/cm³ or some other suitable value. In further embodiments, the doping concentration of the doped liner region 112 is equal to the doping concentration of the pinning region 110 and/or is greater than the doping concentration of the collector region 108. The doped liner region 112 continuously laterally extends from one or more corresponding sidewalls of the first substrate 102 that define the trenches 902 to sides of the collector region 108 and the pinning region 110.

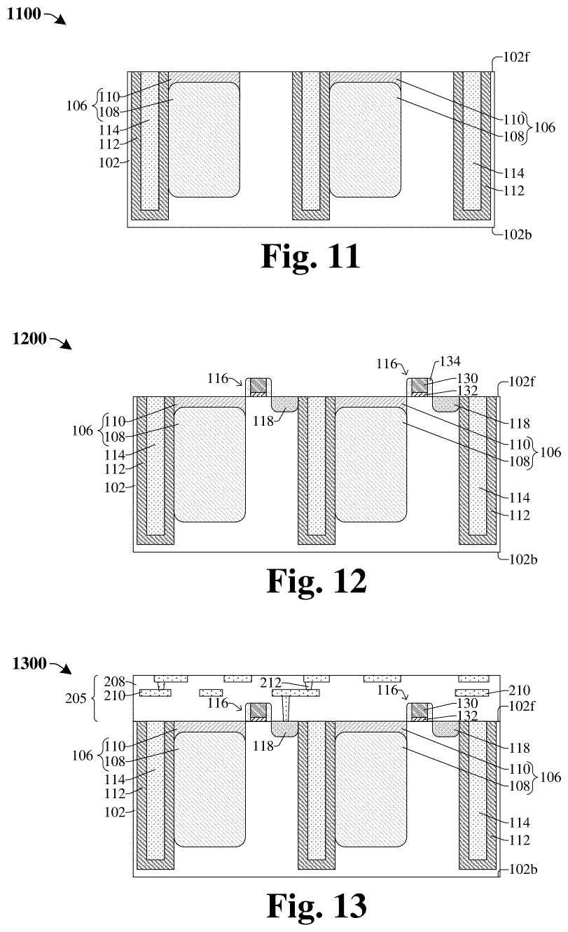

As shown in cross-sectional view 1100 of FIG. 11, an isolation structure 114 is formed in the trenches (902 of FIG. 10). In some embodiments, forming the isolation structure 114 includes depositing (e.g., by chemical vapor deposition (CVD), atomic layer deposition (ALD) process, physical vapor deposition (PVD) process, etc.) or growing (e.g., by a thermal oxidation process or the like) one or more isolation structure materials (e.g., silicon dioxide) in the trenches (902 of FIG. 10) and performing a planarization process (e.g., a chemical mechanical planarization (CMP) process) on the one or more isolation structure materials. A top surface of the isolation structure 114 is coplanar with the front side 102f of the first substrate 102.

In various embodiments, both the doped liner region 112 and the pinning region 110 may be formed in the first substrate 102 after forming the isolation structure 114. In such embodiments, the doped liner region 112 and the pinning region 110 are formed concurrently by an ion implantation process after the isolation structure 114 is disposed in the first substrate 102.

In some embodiments, the isolation structure 114 is formed by a thermal oxidation process that includes growing the isolation structure 114 in the plurality of trenches (902 of FIG. 9). The thermal oxidation process may, for example, include exposing the first substrate 102 to a temperature within a range of 800 to 1,200 degrees Celsius in an oxidizing atmosphere that may include oxygen and another gas (e.g., nitrogen or argon). By virtue of the first substrate 102 comprising the n-type dopants with a relatively high first segregation coefficient k1, the n-type dopants may accumulate along an interface between the first substrate 102 and the isolation structure 114. In various embodiments, the first segregation coefficient k1 is greater than a second segregation coefficient k2 of the p-type dopants of the collector region 108, such that the p-type dopants of the collector region 108 are less likely to diffuse out to the interface between the first substrate 102 and the isolation structure 114. As a result, leakage current in the image sensor is decreased.

In yet further embodiments, the doped liner region 112 may be formed during formation of the isolation structure 114. In such embodiments, the doped liner region 112 is formed when n-type dopants from the first substrate 102 accumulate around the interface between the isolation structure 114 and the first substrate 102 during the thermal oxidation process. In various embodiments, the relatively high first segregation coefficient k1 of the n-type dopants of the first substrate 102 result in the doped liner region 112 having the higher doping concentration compared to other regions of the first substrate 102 adjacent to the collector region 108. In further embodiments, a concentration of the n-type dopants in the doped liner region 112 decreases from surfaces of the isolation structure 114 in directions away from the isolation structure 114. For example, the concentration of the n-type dopants in the doped liner region 112 decreases exponentially from a first sidewall of the isolation structure 114 facing the collector region 108 in a direction towards the collector region 108.

As shown in cross-sectional view 1200 of FIG. 12, a plurality of transfer transistors 116 and floating diffusion nodes 118 are formed on and/or within the first substrate 102. The plurality of transfer transistors 116 are formed on the front side 102f of the first substrate 102. The transfer transistors 116 respectively comprise a transfer gate dielectric 132 on the first substrate 102, a transfer gate electrode 130 on the transfer gate dielectric 132, and a sidewall spacer along sidewalls of the transfer gate electrode 130 and the transfer gate dielectric 132. The floating diffusion nodes 118 are formed in the first substrate 102 by, for example, an ion implantation process or some other suitable fabrication process. In some embodiments, the floating diffusion nodes 118 comprise the second dopants (e.g., boron, indium, aluminum, gallium, etc.) and have the second doping type (e.g., p-type) with a doping concentration within a range of about 10¹⁶ to 10¹⁸ atoms/cm³ or some other suitable value. In various embodiments, the doping concentrations of the floating diffusion nodes 118 are equal to a doping concentration of the collector region 108 and/or are less than a doping concentration of the pinning region 110.

As shown in cross-sectional view 1300 of FIG. 13, a first interconnect structure 205 is formed on the front side 102f of the first substrate 102. The first interconnect structure 205 comprises a plurality of conductive wires 210 and a plurality of conductive vias 212 disposed in an interconnect dielectric structure 208. The conductive wires 210 and the vias 212 are each grouped into a plurality of wire layers and a plurality of via layers that are alternatively sacked. Layers of the first interconnect structure 205 may, for example, be formed by a single damascene process, a dual damascene process, some other suitable fabrication process, or the like.

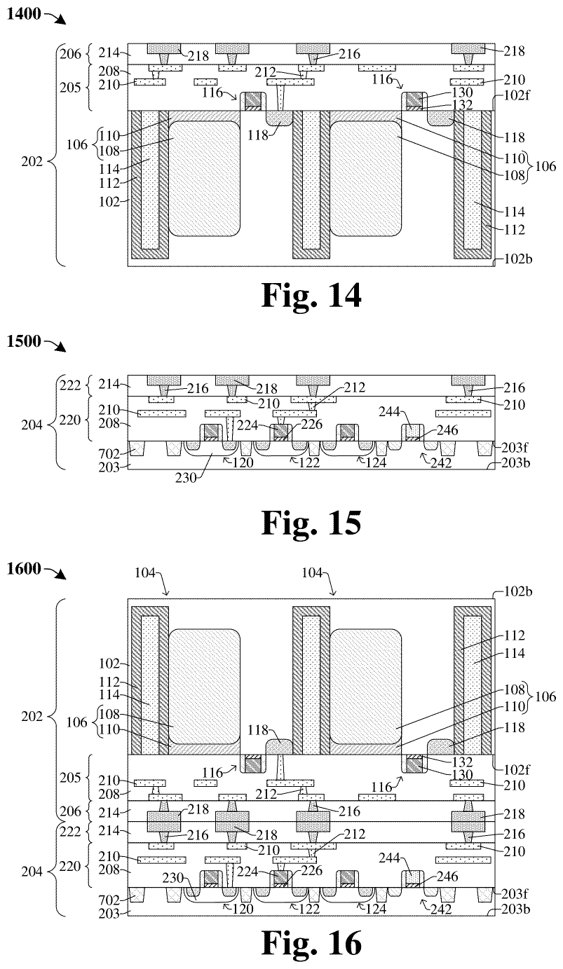

As shown in cross-sectional view 1400 of FIG. 14, a first bond structure 206 is formed on the first interconnect structure 205, thereby defining and/or forming a first IC chip 202. The first bond structure 206 comprises a plurality of conductive bond contacts 216 and a plurality of conductive bond pads 218 in a bond dielectric structure 214. In some embodiments, a process for forming the first IC chip 202 includes the processing steps illustrated and/or described in FIGS. 8-14.

As shown in cross-sectional view 1500 of FIG. 15, a second IC chip 204 is provided or otherwise formed. The second IC chip 204 comprises a second substrate 203, a second interconnect structure 220 on a front side 203f of the second substrate 203, a second bond structure 222 on the second interconnect structure 220, a plurality of pixel transistors 120, 122, 124 and one or more in-pixel transistors 242 in and/or on the second substrate 203. A shallow trench isolation (STI) structure 702 is formed in the second substrate 203. The plurality of pixel transistors 120, 122, 124 are formed on the front side 203f of the second substrate 203. The one or more in-pixel transistors 242 are formed on the front side 203f of the second substrate 203. The second interconnect structure 220 is formed on the front side 203f of the second substrate. The second bond structure 222 is formed on the second interconnect structure 220. In various embodiments, the second IC chip 204 is configured as illustrated and/or described in any one of FIGS. 2A, 2B, 2C, or 7. In further embodiments, the second IC chip 204 comprises an in-pixel circuit (601 of FIG. 6).

As shown in cross-sectional view 1600 of FIG. 16, the first IC chip 202 of FIG. 14 bonded to the second IC chip 204. A first bond interface is disposed between the first bond structure 206 and the second bond structure 222. In some embodiments, bonding the first IC chip 202 to the second IC chip 204 includes conductor-to-conductor bonding and dielectric-to-dielectric bonding. In various embodiments, bonding the first IC chip 202 to the second IC chip 204 forms a plurality of pixels that span the first and second IC chips 202, 204.

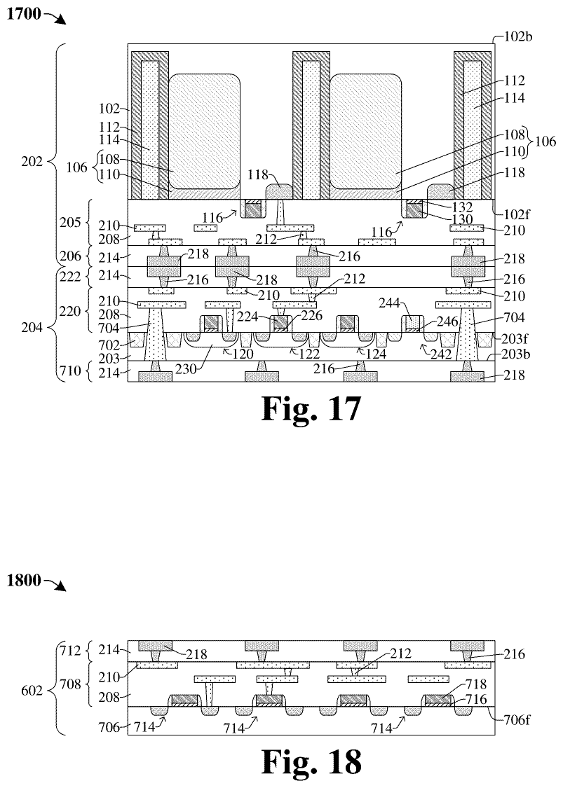

As shown in cross-sectional view 1700 of FIG. 17, a plurality of through substrate vias (TSVs) 704 are formed extending through the second substrate 203 to the second interconnect structure 220 and a third bond structure 710 is formed on a back side 203b of the second substrate 203. The third bond structure 710 comprises a plurality of conductive bond contacts 216 and a plurality of conductive bond pads 218 in a bond dielectric structure 214.

As shown in cross-sectional view 1800 of FIG. 18, a third IC chip 602 is provided or otherwise formed. The third IC chip 602 comprises a third substrate 706, a third interconnect structure 708 on a front side 706f of the third substrate 706, a fourth bond structure 712 on the third interconnect structure 708, and a plurality of semiconductor devices 714 in and/or on the third substrate 706. The semiconductor devices 714 are formed on the front side 706f of the third substrate 706. The third interconnect structure 708 is formed on the front side 706f of the third substrate 706 and is electrically coupled to the plurality of semiconductor devices 714. Further, the fourth bond structure 712 is formed on the third interconnect structure 708. In various embodiments, the third IC chip 602 is configured as illustrated and/or described in FIG. 7. In further embodiments, the third IC chip 602 comprises an application-specific integrated circuit (ASIC) (604 of FIG. 6).

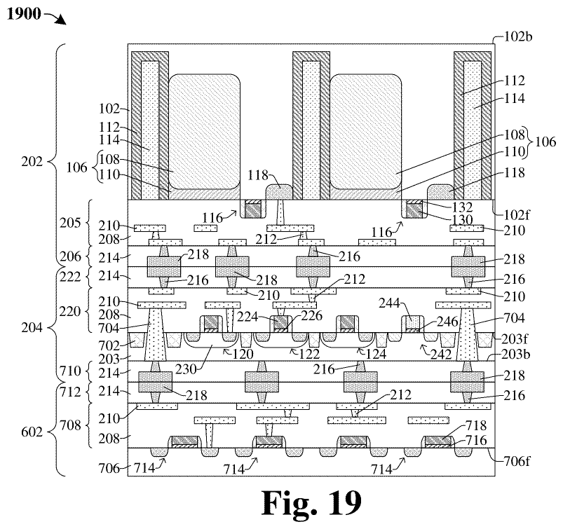

As shown in cross-sectional view 1900 of FIG. 19, the third IC chip 602 is bonded to the second IC chip 204. A second bond interface is disposed between the third bond structure 710 and the fourth bond structure 712. In some embodiments, bonding the third IC chip 602 to the second IC chip 204 includes conductor-to-conductor bonding and dielectric-to-dielectric bonding.

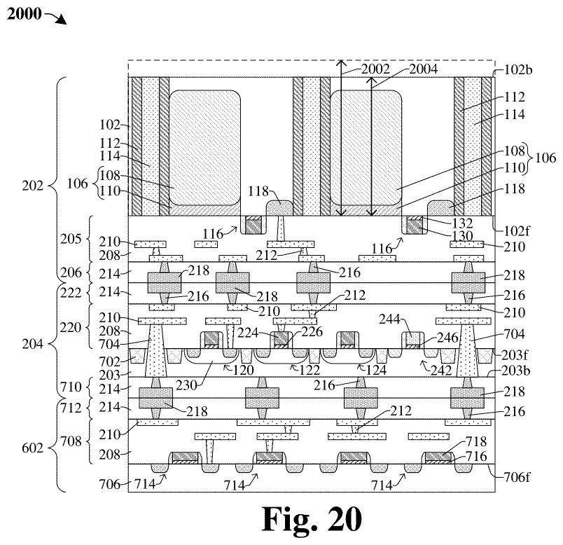

As shown in cross-sectional view 2000 of FIG. 20, a thinning process is performed on the first substrate 102. The thinning process reduces a thickness of the first substrate 102 from a first thickness 2002 to a second thickness 2004. The thinning process may, for example, comprise a CMP process, a mechanical grinding process, or some other suitable process.

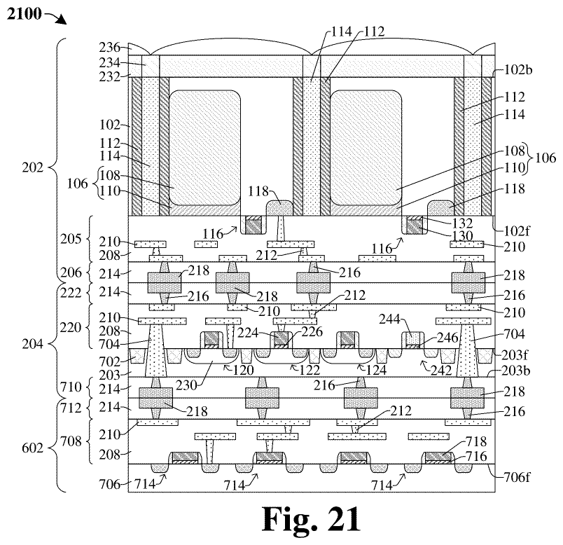

As shown in cross-sectional view 2100 of FIG. 21, a grid structure 234, a plurality of light filters 232, and a plurality of micro-lenses 236 are formed on the back side 102b of the first substrate 102. The grid structure 234 may be formed by depositing a grid structure material on the first substrate 102 and patterning the grid structure material to form a plurality of openings over the plurality of photodetectors 106. The light filters 232 may be formed by depositing and patterning respective color filter layers corresponding to the light filters 232. The micro-lenses 236 may be formed by depositing a micro-lens material over the light filters 232 and patterning the micro-lens material.

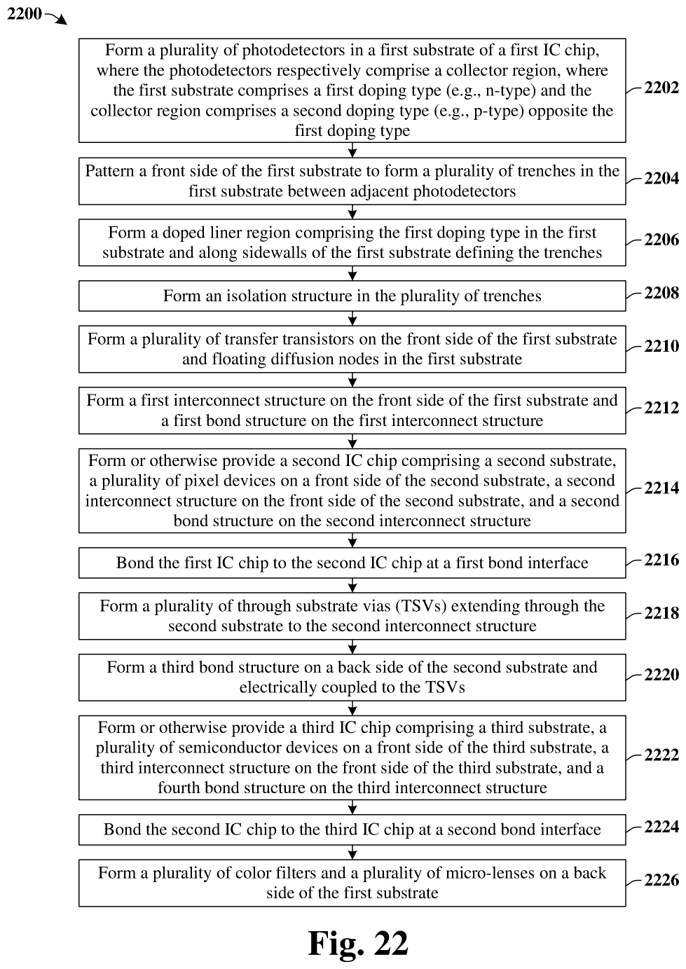

FIG. 22 illustrates a flow diagram 2200 of some embodiments of a method of forming an image sensor comprising photodetectors having low leakage current. While the method is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At act 2202, a plurality of photodetectors are formed in a first substrate of a first IC chip. The photodetectors respectively comprise a collector region. The first substrate comprises a first doping type (e.g., n-type) and the collector region comprises a second doping type (e.g., p-type) opposite the first doping type. FIG. 8 illustrates a cross-sectional view 800 of some embodiments corresponding to act 2202.

At act 2204, a front side of the first substrate is patterned to form a plurality of trenches in the first substrate between adjacent photodetectors. FIG. 9 illustrates a cross-sectional view 900 of some embodiments corresponding to act 2204.

At act 2206, a doped liner region is formed comprising the first doping type in the first substrate and along sidewalls of the first substrate defining the trenches. FIG. 10 illustrates a cross-sectional view 1000 of some embodiments corresponding to act 2206.

At act 2208, an isolation structure is formed in the plurality of trenches. FIG. 11 illustrates a cross-sectional view 1100 of some embodiments corresponding to act 2208.

At act 2210, a plurality of transfer transistors are formed on the front side of the first substrate and floating diffusion nodes are formed in the first substrate. FIG. 12 illustrates a cross-sectional view 1200 of some embodiments corresponding to act 2210.

At act 2212, a first interconnect structure is formed on the front side of the first substrate and a first bond structure is formed on the first interconnect structure. FIGS. 13 and 14 illustrate cross-sectional views 1300 and 1400 of some embodiments corresponding to act 2212.

At act 2214, a second IC chip is formed or otherwise provided. The second IC chip comprises a second substrate, a plurality of pixel devices on a front side of the second substrate, a second interconnect structure on the front side of the second substrate, and a second bond structure on the second interconnect structure. FIG. 15 illustrates a cross-sectional view 1500 of some embodiments corresponding to act 2214.

At act 2216, the first IC chip is bonded to the second IC chip at a first bond interface. FIG. 16 illustrates a cross-sectional view 1600 of some embodiments corresponding to act 2216.

At act 2218, a plurality of through substrate vias (TSVs) are formed extending through the second substrate to the second interconnect structure. FIG. 17 illustrates a cross-sectional view 1700 of some embodiments corresponding to act 2218.

At act 2220, a third bond structure is formed on a back side of the second substrate and is electrically coupled to the TSVs. FIG. 17 illustrates the cross-sectional view 1700 of some embodiments corresponding to act 2220.

At act 2222, a third IC chip is formed or otherwise provided. The third IC chip comprises a third substrate, a plurality of semiconductor devices on a front side of the third substrate, a third interconnect structure on the front side of the third substrate, and a fourth bond structure on the third interconnect structure. FIG. 18 illustrates a cross-sectional view 1800 of some embodiments corresponding to act 2222.

At act 2224, the second IC chip is bonded to the third IC chip at a second bond interface. FIG. 19 illustrates a cross-sectional view 1900 of some embodiments corresponding to act 2224.

At act 2226, a plurality of color filters and a plurality of micro-lenses are formed on a back side of the first substrate. FIG. 21 illustrates a cross-sectional view 2100 of some embodiments corresponding to act 2226.

Accordingly, in some embodiments, the present application relates to an image sensor comprising a substrate having a first doping type, and a photodetector in the substrate comprising a collector region having a second doping type. An isolation structure is disposed in the substrate, and a doped liner region having the first doping type extends from the isolation structure to the collector region. The first doping type is n-type and the second doping type is p-type.

In some embodiments, the present application relates to an image sensor. The image sensor includes a semiconductor substrate comprising a front side opposite a back side; a photodetector disposed in the semiconductor substrate and comprising a collector region and a pinning region, the pinning region is disposed between the collector region and the front side of the semiconductor substrate, wherein the pinning region and the semiconductor substrate comprise a first doping type and the collector region comprises a second doping type opposite the first doping type; an isolation structure in the semiconductor substrate and adjacent to the photodetector; and a doped liner region extending along opposing sidewalls of the isolation structure and comprising the first doping type, wherein the doped liner region extends from sides of the collector and pinning regions to a sidewall of the isolation structure, wherein the first doping type is n-type and the second doping type is p-type.

In some embodiments, the present disclosure relates to an image sensor. The image sensor includes a first integrated circuit (IC) chip comprising a first photodetector and a second photodetector disposed in a first substrate, wherein the first and second photodetectors respectively comprise a p-type collector region and an n-type pinning region; a first p-type floating diffusion node disposed in the first substrate and adjacent to the first photodetector; and an isolation structure disposed in the first substrate and wrapped around the first and second photodetectors; a second IC chip on and coupled to the first IC chip, wherein the second IC chip comprises a first plurality of pixel devices on a second substrate, wherein the first plurality of pixel devices comprises a reset transistor, a source-follower transistor, and a select transistor, wherein a gate of the source-follower transistor is coupled to the first p-type floating diffusion node; and a third IC chip on and coupled to the second IC chip, wherein the third IC chip comprises a plurality of semiconductor devices on a third substrate and coupled to the second IC chip.

In yet other embodiments, the present disclosure relates to a method of forming an image sensor. The method includes forming a photodetector in a semiconductor substrate, wherein the semiconductor substrate comprises a first doping type and a front side opposite a back side, wherein the photodetector comprises a collector region having a second doping type opposite the first doping type; patterning the semiconductor substrate to form a plurality of trenches extending from the front side to a point below the front side; forming a doped liner region along sidewalls of the semiconductor substrate that define the plurality of trenches, wherein the doped liner region comprises the first doping type with a doping concentration different than that of the semiconductor substrate; forming an isolation structure in the plurality of trenches, wherein the doped liner region is disposed along sidewalls of the isolation structure; and forming a floating diffusion node in the semiconductor substrate and laterally offset from the photodetector, wherein the floating diffusion node comprises the second doping type, wherein the first doping type is n-type and the second doping type is p-type.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensor, comprising:
a semiconductor substrate comprising a front side opposite a back side;
a photodetector disposed in the semiconductor substrate and comprising a collector region and a pinning region, the pinning region is disposed between the collector region and the front side of the semiconductor substrate, wherein the pinning region and the semiconductor substrate comprise a first doping type and the collector region comprises a second doping type opposite the first doping type;
an isolation structure in the semiconductor substrate and adjacent to the photodetector; and
a doped liner region extending along opposing sidewalls of the isolation structure and comprising the first doping type, wherein the doped liner region extends from sides of the collector and pinning regions to a sidewall of the isolation structure, wherein the first doping type is n-type and the second doping type is p-type.

2. The image sensor of claim 1, further comprising:
a floating diffusion node in the semiconductor substrate and adjacent to the photodetector, wherein the floating diffusion node comprises the second doping type.

3. The image sensor of claim 2, wherein a doping concentration of the pinning region is greater than doping concentrations of the collector region and the floating diffusion node, wherein a doping concentration of the doped liner region is less than or equal to the doping concentration of the pinning region.

4. The image sensor of claim 2, further comprising:
a transfer transistor comprising a transfer gate structure on the front side of the semiconductor substrate and arranged between the photodetector and the floating diffusion node, wherein the transfer transistor is a p-type transistor.

5. The image sensor of claim 4, further comprising:
a reset transistor comprising a first source/drain region coupled to the floating diffusion node and a second source/drain region coupled to a ground node, wherein the transfer transistor and the reset transistor are configured to selectively electrically couple the collector region to the ground node, wherein a bulk region of the semiconductor substrate around the collector region is electrically coupled to a supply voltage node.

6. The image sensor of claim 5, further comprising:
a source-follower transistor comprising a gate structure coupled to the floating diffusion node and a first source/drain region coupled to the ground node; and
a select transistor comprising a first source/drain region coupled to a second source/drain region of the source-follower transistor, wherein the reset transistor, the source-follower transistor, and the select transistor are respectively configured as a p-type transistor.

7. The image sensor of claim 6, wherein the photodetector and the transfer transistor are disposed on a first integrated circuit (IC) chip, wherein the reset transistor, the source-follower transistor, and the select transistor are disposed on a second semiconductor substrate of a second IC chip, wherein the second IC chip is disposed on the first IC chip.

8. The image sensor of claim 1, wherein the isolation structure and the doped liner region continuously laterally extend from the front side of the semiconductor substrate to the back side of the semiconductor substrate.

9. An image sensor, comprising:
a first integrated circuit (IC) chip comprising:
a first photodetector and a second photodetector disposed in a first substrate, wherein the first and second photodetectors respectively comprise a p-type collector region and an n-type pinning region;
a first p-type floating diffusion node disposed in the first substrate and adjacent to the first photodetector; and
an isolation structure disposed in the first substrate and wrapped around the first and second photodetectors;
a second IC chip on and coupled to the first IC chip, wherein the second IC chip comprises a first plurality of pixel devices on a second substrate, wherein the first plurality of pixel devices comprises a reset transistor, a source-follower transistor, and a select transistor, wherein a gate of the source-follower transistor is coupled to the first p-type floating diffusion node; and
a third IC chip on and coupled to the second IC chip, wherein the third IC chip comprises a plurality of semiconductor devices on a third substrate and coupled to the second IC chip.

10. The image sensor of claim 9, wherein the first plurality of pixel devices are each configured as a p-type transistor.

11. The image sensor of claim 10, wherein the second IC chip further comprises an in-pixel circuit comprising one or more n-type transistors on the second substrate, wherein the plurality of semiconductor devices are part of an application-specific integrated circuit (ASIC) that is electrically coupled to the in-pixel circuit.

12. The image sensor of claim 9, further comprising:
an n-type doped liner region along sidewalls of the isolation structure, wherein the n-type doped liner region is disposed between the isolation structure and the first and second photodetectors.

13. The image sensor of claim 12, wherein the n-type pinning region comprises a first dopant and the n-type doped liner region comprises a second dopant different from the first dopant.

14. The image sensor of claim 9, wherein the isolation structure continuously laterally wraps around an outer perimeter of the first photodetector and around an outer perimeter of the second photodetector, wherein a segment of the isolation structure is disposed between the first and second photodetectors.

15. The image sensor of claim 9, further comprising:
a second isolation structure in the first substrate and overlying the first p-type floating diffusion node.

16. A method for forming an image sensor, comprising:
forming a photodetector in a semiconductor substrate, wherein the semiconductor substrate comprises a first doping type and a front side opposite a back side, wherein the photodetector comprises a collector region having a second doping type opposite the first doping type;
patterning the semiconductor substrate to form a plurality of trenches extending from the front side to a point below the front side;
forming a doped liner region along sidewalls of the semiconductor substrate that define the plurality of trenches, wherein the doped liner region comprises the first doping type with a doping concentration different than that of the semiconductor substrate;
forming an isolation structure in the plurality of trenches, wherein the doped liner region is disposed along sidewalls of the isolation structure; and
forming a floating diffusion node in the semiconductor substrate and laterally offset from the photodetector, wherein the floating diffusion node comprises the second doping type, wherein the first doping type is n-type and the second doping type is p-type.

17. The method of claim 16, further comprising:
forming a transfer gate electrode on the front side of the semiconductor substrate and between the collector region and the floating diffusion node, wherein the transfer gate electrode comprises a plurality of gate electrode layers having a p-type work function.

18. The method of claim 16, wherein the photodetector comprises a pinning region disposed between the collector region and the front side of the semiconductor substrate, wherein the pinning region comprises the first doping type, and wherein the doped liner region and the pinning region are formed concurrently with one another.

19. The method of claim 18, wherein doping concentrations of the pinning region and the doped liner region are greater than a doping concentration of the collector region.

20. The method of claim 16, further comprising:
forming a first interconnect structure on the semiconductor substrate and a first bond structure on the first interconnect structure;
forming a plurality of pixel devices on a front side of a second semiconductor substrate, wherein the plurality of pixel devices include a source-follower transistor, a reset transistor, and a select transistor, wherein the plurality of pixel devices are each configured as a p-type transistor;
forming a second interconnect structure on the second semiconductor substrate and a second bond structure on the second interconnect structure; and
bonding the first bond structure to the second bond structure, wherein a gate of the source-follower transistor is electrically coupled to the floating diffusion node.
